(19) United States
(12) Patent Application Publication
(10) Pub. No.: US 2012/0118367 A1
(43) Pub. Date: May 17, 2012

(54) NON-PLANAR/CURVED DYE-SENSITIZED SOLAR CELL AND A METHOD OF MANUFACTURING THE SAME

(75) Inventors: Mi Yeon Song, Seoul (KR); Sang Hak Kim, Seoul (KR); Yong Jun Jang, Seongnam (KR); Won Jung Kim, Seoul (KR); Yong Gu Kim, Hwaseong (KR); In Woo Song, Hwaseong (KR); Ki Chun Lee, Seoul (KR)

(73) Assignee: HYUNDAI MOTOR COMPANY, Seoul (KR)

(21) Appl. No.: 13/016,447

(22) Filed: Jan. 28, 2011

(30) Foreign Application Priority Data
Nov. 11, 2010 (KR) 10-2010-0112353

(51) Int. Cl. H01L 31/02; H01L 31/0256

(52) U.S. Cl. 136/256; 438/72; 438/85; 257/E31.003

(57) ABSTRACT

Featured are a non-planar curved dye-sensitized solar cell and a method of manufacturing such a solar cell. In particular aspects, such methods include preparing two curved substrates, forming a first curved conductive substrate for a working electrode and a second curved conductive substrate for a counter electrode, coating a metal electrode and a protection film on each of the first and second curved conductive substrates, forming the working electrode by coating a semiconductor oxide electrode film on a concave surface of the first curved conductive substrate and by adsorbing a dye in the semiconductor oxide electrode film, forming the counter electrode by coating a catalytic electrode on a convex surface of the second curved conductive substrate, and joining the working electrode with the counter electrode and injecting an electrolyte in between the working electrode and the counter electrode.

### CROSS-REFERENCE TO RELATED APPLICATION

This application claims under 35 U.S.C. §119(a) priority to and the benefit of Korean Patent Application No. 10-2010-0112353 filed Nov. 11, 2010, the entire contents of which are incorporated herein by reference.

### BACKGROUND

(a) Technical Field

The present invention generally to relates to dye-sensitized solar cells and methods for manufacturing same, more particularly relates to non-planar dye-sensitized solar cells and methods for manufacturing such a solar cell, yet more particularly relates to a curved dye-sensitized solar cell and methods of manufacturing such a solar cell, and more specifically to methods of manufacturing a non-planar/curved dye-sensitized solar cell using a glass substrate having a curvature.

(b) Background Art

Growing interest in eco-friendly energy sources has led to the use of photoelectric conversion elements, such as solar cells. Among them, commercially available silicon-based solar cells have been used as sunroofs for vehicles. These silicon-based solar cells, however, have a very limited use due to opacity and high costs.

Dye-sensitized solar cells reaching commercialization have drawn attention as an alternative and thus research has been in progress to apply the dye-sensitized solar cell to various fields, such as vehicles or BIPV (Building Integrated Photovoltaics).

In general, a dye-sensitized solar cell includes a working electrode and a counter electrode that are joined to each other. An I⁻/I₃⁻-based electrolyte is injected between the working electrode and the counter electrode. The working electrode includes a transparent conductive substrate and a semiconductor oxide film coated on the transparent conductive substrate. The semiconductor oxide film is formed of TiO₂ adsorbed with a Ru-based dye. The counter electrode is coated with a catalytic electrode using Pt.

Because of the advantages, such as low manufacturing costs, formation of transparent conductive substrates, and various designs, dye-sensitized solar cells have been gaining popularity and their applications have been extended including dye-sensitized solar cells to roofs or windows of buildings. There also has been an attempt to replace the sunroofs of vehicles with dye-sensitized solar cells.

Most of dye-sensitized solar cell modules are of flat types (e.g., planar) and thus it is difficult to apply such flat-type dye-sensitized solar cell modules to curved surfaces, such as sunroofs for vehicles. Thus, there is a need for the development of curved dye-sensitized solar cell modules that can be applied, as is, to curved surfaces.

For example, Japanese Patent Application No. 2005-207242, which is incorporated herein by reference, describes a method of manufacturing a dye-sensitized solar cell using a glass substrate having a three-dimensional curved shape and applying the same to glass roofs, rear windows, or door glass. In the described method, two flat-type glass substrates are first prepared for a working electrode and a counter electrode and then are bent at a temperature so as to have a curved shape. The bent glass substrates are then coated with TiO₂ by electrodeposition.

The described method is, however, disadvantageous in that the transparent electrode film can be damaged or inherent characteristics of the used glass can be lost while bending the glass substrates.

Moreover, the working electrode and counter electrode formed using the described method can have different shapes from each other. For example, one of the working and counter electrodes has a concave shape and the other has a convex shape. Then, the two electrodes may not be completely joined to each other.

Furthermore, when the electrodeposition is used for forming the TiO₂ electrode film on the curved conductive substrates, it is difficult to adjust the amount of electrodeposition solution and conditions for electrodepositon, such as applied voltage or electrodeposition time.

Thus, there continues to be a need for providing a non-planar or curved dye-sensitized solar cell that is appropriate for non-planar or curved structures, such as sunroofs or panoramic sunroofs of vehicles. There also continues to be a need for methods of manufacturing such non-planar or curved dye-sensitized solar cells.

The above information disclosed in this Background section is only for enhancement of understanding of the background of the invention and therefore it may contain information that does not form the prior art that is already known in this country to a person of ordinary skill in the art.

### SUMMARY OF THE DISCLOSURE

According to one aspect of the present invention, there is featured a method of manufacturing a non-planar dye-sensitized solar cell. Such a method includes, providing a first non-planar substrate and a second non-planar substrate, each of the first and second non-planar substrates being arranged so as to have a complementary opposing surface to each other. Such a method further includes forming a first non-planar conductive substrate as a working electrode and forming a second non-planar conductive substrate as a counter electrode. Such forming includes coating the opposing surface of the first non-planar substrate with a conductive film so as to yield a first non-planar conductive substrate and coating the opposing surface of the second non-planar conductive substrate with another conductive film so as to yield a second non-planar conductive substrate.

Such forming further includes: (a) coating each of the first and second non-planar conductive substrates with a metal electrode and a protection film, (b) coating the first non-planar conductive substrate with a semiconductor oxide electrode film and adsorbing a dye in the semiconductor oxide electrode film, and (c) coating the second non-planar conductive substrate with a catalytic electrode.

Such a method further includes joining the working electrode with the counter electrode; and injecting an electrolyte in between the working electrode and the counter electrode.

In an embodiment of the present invention, the non-planar substrates are prepared using any of a number of techniques known to those skilled in the art and otherwise appropriate for the present invention. In one exemplary embodiment, each of the non-planar substrates is prepared using injection molding so that the opposing surfaces have a desired predetermined shape or configuration such as for example, a curved shape having predetermined rate of curvature.

In further embodiments, each of the non-planar substrates has a first surface configuration corresponding to an opposing horizontal surface configuration of a portion of a vehicle to which the solar cell is to be applied, and a second surface configuration corresponding to an opposing vertical surface configuration of the portion of the vehicle. In exemplary embodiments, the opposing surfaces of the vehicle are curved, thus each of the curved substrates has a first curvature equal to a horizontal curvature of the portion of the vehicle and a second curvature equal to a vertical curvature of the portion of the vehicle. In yet further embodiments, each of the non-planar or curved substrates has same curvature or surface configuration as that of a sunroof or panoramic roof of the vehicle.

In yet further embodiments, such methods further include providing a jig having the same configuration or curvature as that of the non-planar or curved substrates that is mounted in a coating machine for the non-planar or curved substrate. The jig is further arranged so that the distance between a source for deposition of the coating machine and the opposing surface of the non-planar or curved substrates is constantly maintained at regular intervals to coat an electrode film having a uniform thickness with the curved substrates held by the jig.

According to another aspect of the present invention, there is featured another method, such a method is for manufacturing a curved dye-sensitized solar cell comprising preparing two curved substrates, each having a curvature, and forming a first curved conductive substrate for a working electrode by coating a conductive film on a concave surface of one of the curved substrates and a second curved conductive substrate for a counter electrode by coating a conductive film on a convex surface of the other curved substrate. Such methods include coating a metal electrode and a protection film on each of the first and second curved conductive substrates, forming the working electrode by coating a semiconductor oxide electrode film on a concave surface of the first curved conductive substrate and by adsorbing a dye in the semiconductor oxide electrode film, and forming the counter electrode by coating a catalytic electrode on a convex surface of the second curved conductive substrate. Such methods further include joining the working electrode with the counter electrode and injecting an electrolyte in between the working electrode and the counter electrode.

In further embodiments such providing includes preparing each of the curved substrates using any of a number of techniques known to those skilled in the art. In an exemplary embodiment, each of the curved substrates is prepared by injection molding so as to have a predetermined rate of curvature.

In yet further embodiments, each of the curved substrates has a first curvature equal to a horizontal curvature of a portion of a vehicle to which the solar cell is applied and a second curvature equal to a vertical curvature of the portion of the vehicle.

In yet further embodiments, each of the curved substrates is configured so as to have the same curvature as that of a sunroof or panoramic roof of a vehicle.

In yet further embodiments, such methods of the present invention include providing a jig having the same curvature as that of the curved substrates that is mounted in a coating machine for a curved substrate. Such a jig is configured so that the distance between a source for deposition of the coating machine and the curved substrates is constantly maintained at regular intervals to coat an electrode film having a uniform thickness with the curved substrates held by the jig.

In yet further embodiments, such methods further include providing a squeezer having the same curvature as a curvature of the curved substrates or surface arrangement for a non-planar substrates that is mounted in a screen printer for a curved substrate to coat an electrode film having a uniform thickness on the non-planar/curved substrates, wherein the coating is performed while adjusting a tension of a plate for screen printing.

In further embodiments, such methods further comprise patterning the conductive films of the non-planar/curved substrates, wherein a jig is mounted in a laser scriber for uniformly patterning the conductive films to maintain the distance between a laser part and the non-planar/curved conductive substrates at regular intervals.

In further embodiments, such methods includes a pre-treatment step that is on the semiconductor oxide electrode film of the first conductive substrate using a titanium tetrachloride-based compound or a titanium alkoxide-based compound.

In yet further embodiments, the conductive films, the metal electrodes, the protection films, the semiconductor oxide electrode film, and the catalytic film are coated so as to have a uniform thickness using a method selected from the group consisting of a screen printing method, an electrospray method, a spray printing method, an inkjet printing method, a MOCVD method, and a CVD method.

In yet further embodiments, one of color glass and a translucent color film can be attached on a convex surface of the first curved conductive substrate and a concave surface of the second curved conductive substrate to enhance ornamentality. In the case of non-planar substrates, one of a color glass and a translucent color film can be attached on an opposing surface of the first conductive substrate and an opposing surface of the second conductive substrate to enhance ornamentality

In yet further embodiments, a reflection film is attached on a concave surface of the second curved conductive surface to increase efficiency. Similarly, such a reflective film can be attached to an opposing surface of the first conductive substrate and an opposing surface of the second conductive substrate.

In yet further embodiments, a condenser lens is mounted on a convex surface of the first curved substrate or an outside surface of the first conductive non-planar substrate, to increase efficiency.

According to the above-described aspects and/or embodiments of the present invention, a dye-sensitized solar cell can be manufactured that has low manufacturing costs and is appropriate for curved or non-planar structures, such as general sunroofs or panoramic sunroofs for vehicles. Such a dye-sensitized solar cell of the present invention is also applicable for various purposes, such as BIPV, vehicles, or electronic applications.

It is understood that the term “vehicle” or “vehicular” or other similar term as used herein is inclusive of motor vehicles in general such as passenger automobiles including sports utility vehicles (SUV), buses, trucks, various commercial vehicles, watercraft including a variety of boats and ships and the like, and includes hybrid vehicles, electric vehicles, plug-in hybrid vehicles, hydrogen powered vehicles and other alternative fuel vehicles (e.g., fuels derived from resources other than petroleum).

It is understood that the term non-planar substrate describes a substrate configuration in which the substrate has a three dimensional shape. A curved substrate generally describes a non-planar substrate that is curved in at least one direction (e.g., curved about the long the long axis of the substrate, however, such a curved substrate can be curved about a long and short axis.

Other aspects and embodiments of the present invention are described herein.

### BRIEF DESCRIPTION OF THE DRAWINGS

The above and other features of the present invention will now be described in detail with reference made to the following detailed description taken in conjunction with the accompanying drawings which are given hereinbelow by way of illustration only, and thus are not limitative of the present invention, wherein like reference characters denote corresponding parts throughout the several views, and wherein:

FIG. 1 is a schematic view schematically illustrating a general dye-sensitized solar cell;

FIG. 2 is an illustrative view illustrating the flow and related structure of a method of manufacturing a non-planar/curved dye-sensitized solar cell according to the present invention;

FIG. 3(a) is an illustrative view illustrating a surface of a flat conductive substrate having a FTO (SnO₂: F) transparent conductive film commercially available from Pilkington Corporation;

FIG. 3(b) is an illustrative view illustrating an SEM image of a curved conductive substrate manufactured according to an embodiment of the present invention;

FIG. 4 is an illustrative view showing placement of a non-planar/curved dye-sensitized solar cell according to the present invention over a sunroof, where thenonplanar/curved substrate is printed with a TiO₂ pattern having a predetermined thickness according to an embodiment of the present invention;

FIG. 5 is an illustrative view showing a TiO₂ electrode film that is coated on a non-planar/curved conductive substrate according to an embodiment of the present invention;

FIG. 6 is an illustrative view showing a non-planar/curved dye-sensitized solar cell module manufactured according to the present invention;

FIGS. 7(a),(b) are various illustrative views of an exemplary curved dye-sensitized solar cell manufactured according to the present invention;

FIGS. 8(a),(b) are various cross-sectional views illustrating a non-planar/curved dye-sensitized solar cell according to the present invention; and

FIG. 9 is a cross-sectional view illustrating another non-planar/curved dye-sensitized solar cell according to the present invention.

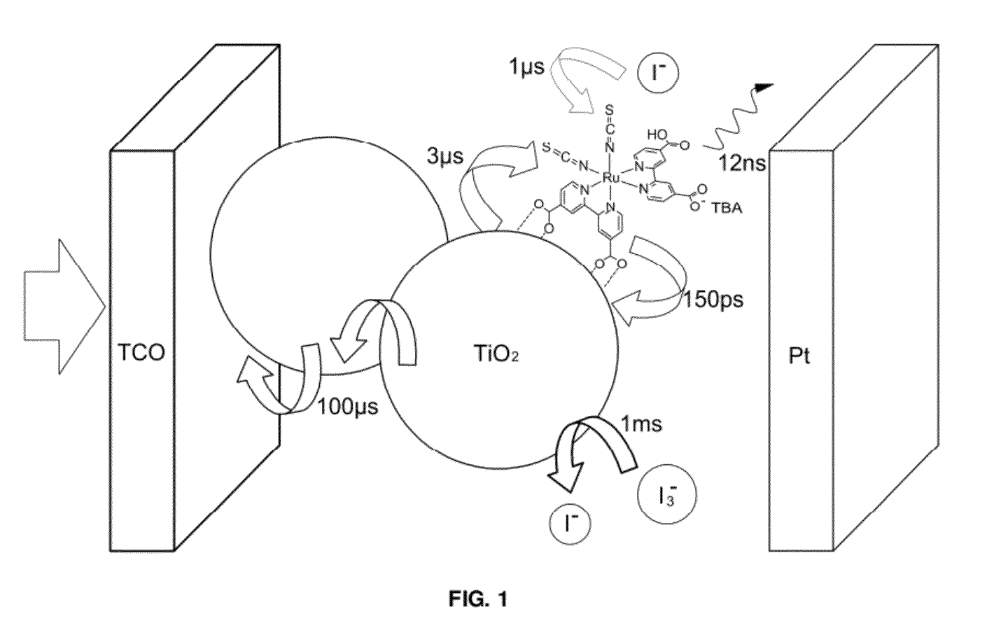

### DETAILED DESCRIPTION

In aspects/embodiments of the present invention there is featured/provided methods for manufacturing a non-planar dye-sensitized solar cell. Such methods include providing a first non-planar substrate and a second non-planar substrate, each of the first and second non-planar substrates being arranged so as to have a complementary opposing surface to each other. In further aspects/embodiments, such non-planar substrates are curved substrates. Such methods further include forming a first non-planar conductive substrate as a working electrode and forming a second non-planar conductive substrate as a counter electrode. Such forming includes coating the opposing surface of the first non-planar substrate with a conductive film so as to yield a first non-planar conductive substrate and coating the opposing surface of the second non-planar conductive substrate with another conductive film so as to yield a second non-planar conductive substrate.

Such forming further includes: (a) coating each of the first and second non-planar conductive substrates with a metal electrode and a protection film, (b) coating the first non-planar conductive substrate with a semiconductor oxide electrode film and adsorbing a dye in the semiconductor oxide electrode film, and (c) coating the second non-planar conductive substrate with a catalytic electrode.

Such methods further includes joining the working electrode with the counter electrode; and injecting an electrolyte in between the working electrode and the counter electrode.

In an embodiment of the present invention, the non-planar substrates are prepared using any of a number of techniques known to those skilled in the art and otherwise appropriate for the present invention. In an exemplary embodiment, each of the non-planar substrates is prepared using injection molding so that the opposing surfaces have a desired predetermined shape or configuration such as for example, a curved shape having a predetermined rate of curvature.

In further embodiments, each of the non-planar substrates has a first surface configuration corresponding to an opposing horizontal surface configuration of a portion of a vehicle to which the solar cell is to be applied, and a second surface configuration corresponding to an opposing vertical surface configuration of the portion of the vehicle. In exemplary embodiments, the opposing surfaces of the vehicle are curved and so each of the curved substrates has a first curvature equal to a horizontal curvature of the portion of the vehicle and a second curvature equal to a vertical curvature of the portion of the vehicle. In yet further embodiments, each of the non-planar/curved substrates has same curvature or surface configuration as that of a sunroof or panoramic roof of the vehicle.

In yet further embodiments, such methods further include providing a jig having the same configuration or curvature as that of the non-planar or curved substrates that is mounted in a coating machine for the non-planar or curved substrate. The jig is further arranged so that the distance between a source for deposition of the coating machine and the opposing surface of the non-planar or curved substrates is constantly maintained at regular intervals to coat an electrode film having a uniform thickness with the curved substrates held by the jig.

The aspects/embodiments of the present invention provide a method of manufacturing a nonplanar/curved dye-sensitized solar cell module appropriate for application to curved structures, such as general sunroofs or panoramic sunroofs.

Such non-planar/curved glass substrates are manufactured so as to have the same curvature or surface configuration as that of a structure to which the solar cell module is applied, such as a general or panoramic sunroof, and a working electrode and a counter electrode are formed using the curved glass substrates. The working and counter electrodes are joined to each other, thus completing a curved dye-sensitized solar cell.

A sunroof typically has different curvatures R1 and R2 in lateral and longitudinal directions. A non-planar/curved substrate is produced to have different curvatures R1 and R2 in lateral and longitudinal directions, and then the curved substrate is coated with a conductive film by performing SPD (Spray Pyrolysis Deposition), CVD (Chemical Vapor Deposition), Sputtering, pad printing, flexo printing, or gravure printing on FTO (Flourine doped tin oxide), ITO (indium tin oxide), IZO (Indium Zinc Oxide), or AZO (Aluminum-doped Zinc Oxide).

A working electrode is produced by forming a TiO₂ electrode film adsorbed with a dye on the non-planar/curved conductive substrate, and a counter electrode is produced by coating a platinum catalytic electrode on the non-planar/curved conductive substrate. The working electrode and the counter electrode are joined to each other, thus completing a non-planar/curved dye-sensitized solar cell module.

A method of manufacturing the non-planar/curved dye-sensitized solar cell module is described in greater detail below. To produce non-planar substrates such as curved substrates 10 and 20 having two curvatures R1 and R2, a jig is first manufactured that has the same curvatures or surface profile or configuration as those of a structure, such as a general or panoramic sunroof for vehicles, to which the solar cell module is applied (hereinafter, referred to as “target structure”). The following discussion refers to curved substrates to simplify the discussion, however, it shall be understood that the discussion also applies to non-planar substrates. Then, curved substrates having the two curvatures R1 and R2 are formed by applying the jig to a glass material. According to an embodiment of the present invention, the curved substrates can be manufactured by bending a flat substrate so that it yields presents the two curvatures.

An FTO conductive film 12 having a uniform thickness is coated on a concave surface of one of the curved substrates 10 and 20, for example, the curved substrate 10 to produce a curved conductive substrate for a working electrode, and a conductive film 22 is coated on a convex surface of the other curved substrate, for example, the curved substrate 20 to produce a curved conductive substrate for a counter electrode.

According to the material of the curved substrates 10 and 20, in further embodiments, a barrier film is formed of silicon dioxide on the curved substrates 10 and 20 before coating the FTO.

According to an embodiment of the present invention, the curved conductive substrates after forming the conductive films 12 and 22 on the curved substrates 10 and 20 are subjected to patterning of the conductive films 12 and 22 by using a laser scriber.

In yet further embodiments and for uniform patterning of the conductive films 12 and 22, the laser scriber has a jig that maintains a predetermined interval between a laser part and the curved conductive substrates.

In further embodiments, the jig supports support the curved conductive substrates to be seated without floating because of having the same curvatures as those of the curved substrates 10 and 20.

The curved conductive substrates move along X and Y axes while being patterned by the jig, and the laser part moves along X, Y, and Z axes (that is, in three dimension) while emitting a laser beam, so that the conductive films 12 and 22 having a uniform pattern are formed on the curved substrates 10 and 20, thereby producing the curved conductive substrates having a uniform pattern.

In further embodiments, the curved conductive substrate for a working electrode is subjected to a pre-treatment using a titanium tetrachloride-based or titanium alkoxide-based compound, for example, such as titanium isopropoxide, titanium propoxide, titanium (IV) butoxide, etc. According to an embodiment, dip coating or spray coating may be employed to generate a uniform film.

Next, screen printing or inkjet printing is used to form metal electrodes 14 and 24 (for example, silver electrodes). Considering the curvatures of the curved conductive substrates, a tool that can perform printing on curved surfaces is used for the printing method and thus metal electrodes can be produced that have the same uniformity as that achievable in the case of forming metal electrodes on flat substrates.

The tool that can perform printing on curved surfaces refers to tools or machines as are known in the art or hereinafter developed that can perform a coating process on a curved surface while moving along the curved surface, and can include any coateres that perform a coating process according to an embodiment of the present invention, such as, but not limited to, a screen printer for curved substrates, an inkjet printer for curved substrates, or a spray coater for curved surfaces.

In further embodiments, the metal electrodes 14 and 24 are dried and sintered, and glass frit is coated on the sintered metal electrodes, thus forming metal electrode protection films 16 and 26. The glass frit may sufficiently cover the metal electrodes 14 and 24. The glass frit can be printed on the curved conductive substrate using the same method (for example, screen printing method or inkjet printing method) as that of the metal electrodes 14 and 24.

The protection films 16 and 26 for protecting the metal electrodes 14 and 24 can be formed using a UV curing agent instead of the glass frit.

In further embodiments and among the curved substrates 10 and 20 coated with the metal electrode protection films 16 and 26, the curved substrate 10 is subjected to a pre-treatment for a semiconductor oxide electrode film 18 and then coated with the semiconductor oxide electrode film 18 using TiO₂.

In further embodiments, a screen printing method is used to form the semiconductor oxide electrode film 18. After masking the metal electrode 14 and the metal electrode protection film 16, a spraying process is performed to form a TiO₂ semiconductor oxide electrode film 18. TiO₂ particles, each having a diameter of 10 to 20 nm, are generally used to manufacture a translucent dye-sensitized solar cell. According to an exemplary embodiment, for the TiO₂ particles for a scattering layer, each particle has a diameter ranging from 400 nm to 500 nm may also be used for enhanced efficiency and design.

The semiconductor oxide electrode film 18 (for example, TiO₂ electrode film) may have a thickness of 10 to 20 um. The thickness of the semiconductor oxide electrode film 18 may be varied depending on viscosity of TiO₂ paste, thickness of a plate used for screen printing, or repeated number of times of coating.

While forming the conductive films 12 and 22, the metal electrodes 14 and 24, the metal electrode protection films 16 and 26, the semiconductor oxide electrode film 18, and the catalytic electrode 28 on the curved substrates using, for example, a coater for flat substrates, there may occur a difference in thickness between an edge portion and a central portion due to curvature of the curved substrates 10 and 20, thus lowering film uniformity. In further embodiments and so as to uniformly form the films, a coating process is performed by a coater mounted with a jig having the same curvature as that of the curved substrates 10 and 20 while maintaining a predetermined distance between the curved substrates and a deposition source of a coater for curved substrates (which are devices for depositing a coating material on a coating surface, such as a spray gun or sputter target) with the curved substrates 10 and 20 held by the jig.

In a further embodiment, a motor is used to provide mobility to the deposition source to maintain the predetermined distance. According to an embodiment, the motor can be mounted at the jig (which has the same curvature as that of the curved substrates as described above) to move the curved substrates. It should be recognized that any of a number of techniques and/or devices or apparatuses known to those skilled in the art or hereinafter developed which can control the movement of the deposition source or adapted for such use are contemplated for use in the present invention.

An injection hole for injecting an electrolyte is formed in the conductive substrate for the counter electrode using a laser apparatus, such as a laser scriber, before coating a catalytic electrode 28 (for example, a platinum electrode). Next, the conductive substrate for the counter electrode is subjected to a screen printing or spraying process to form the catalytic electrode 28 and then subjected to a thermal treatment.

After preparing the working electrode and the counter electrode, the semiconductor oxide electrode film 18 for the working electrode is soaked in N719 dye for about 24 hours so that the dye may be adsorbed on the semiconductor oxide electrode film 18. Although N719 dye has been used to represent violet, the present invention is not limited thereto and other dyes that are appropriate for the intended use can be used in the present invention. According to an embodiment, various types of dyes, such as an organic pigment, and various colors, such as black, may be used.

Thereafter, the semiconductor oxide electrode film 18 that is adsorbed with the dye, is washed by a washing agent, such as ethanol. Then, the working electrode and the counter electrode are joined to each other using a UV curing agent or SURLYN™ tape. Thereafter, an electrolyte is injected into the module.

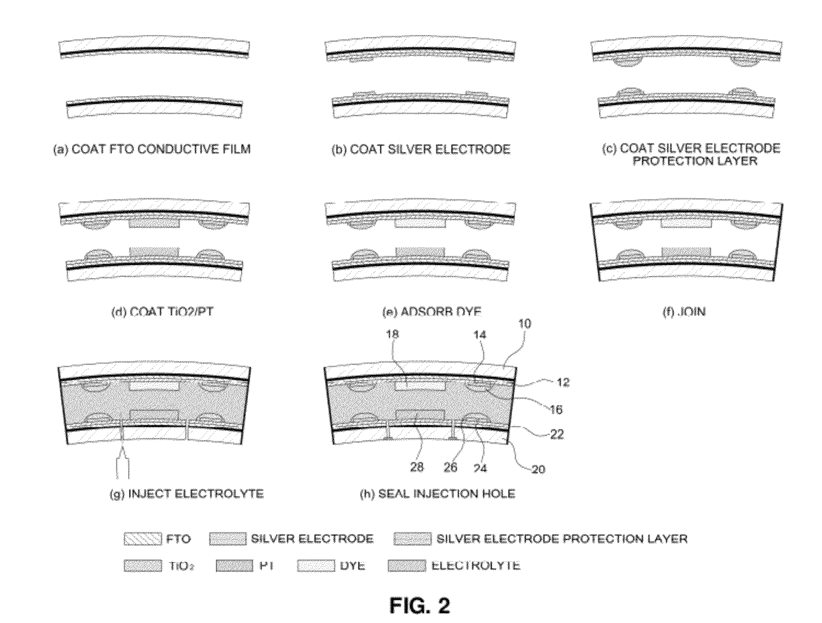

The electrolyte is injected through the injection hole by a syringe and then the injection hole is sealed to prevent the electrolyte from leaking as shown in FIGS. 2 and 6. The material sealing the hole is any of a number of materials known to those skilled in the art and otherwise appropriate for the intended use.

In further embodiments, various colored organic dyes, such as Ru-based organic dye, may be used in terms of ornamentality. In yet further embodiments, various types of color glass or translucent color films may be used to match the color of a vehicle to which the solar cell is applied.

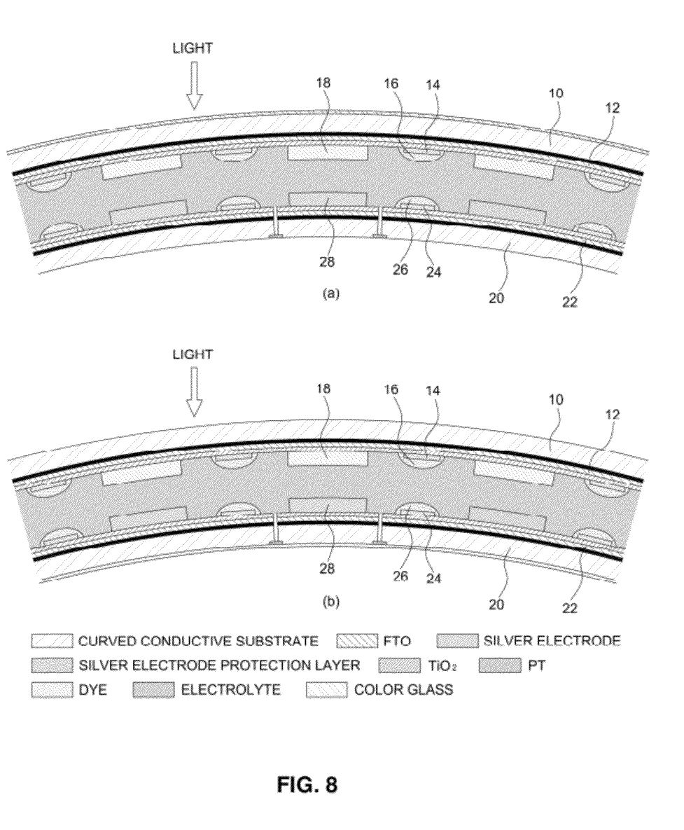

As shown in FIG. 8, color glass or a translucent color film can be attached on a convex surface of the curved substrate 10 for working electrode and a concave surface of the curved substrate 20 for counter electrode to provide additional color, thus allowing for dye-sensitized solar cells of various colors.

According to an embodiment of the present invention, color glass or a translucent color film is attached to only one of a convex surface of the curved substrate 10 for working electrode and a concave surface of the curved substrate 20 for counter electrode.

FIG. 8(a) illustrates an example where the color glass is attached onto an outer surface of a vehicle. In this case, considering the efficiency of the dye-sensitized solar cell, chroma and brightness of the color glass are selected not to block incident light.

FIG. 8(b) illustrates an example where color glass is attached onto an inner surface of a vehicle. In this case, external light may enter into the vehicle irrespective of existence of the color glass and thus a user may select color glass of a desired color without being limited to color glass having specific chroma or brightness.

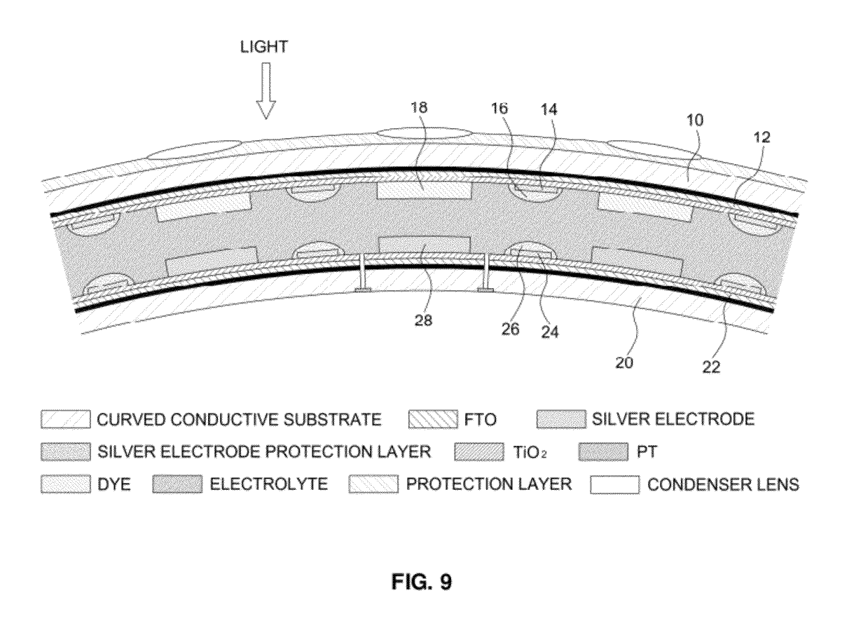

FIG. 9 is an illustrative view illustrating a further embodiment in which condenser lenses are applied to a curved dye-sensitized solar cell module. Referring to FIG. 9, condenser lenses are attached on a convex surface of the curved substrate 10 for working electrode, thus enhancing efficiency of the module.

In further embodiments, protection glass for protecting the curved substrate 10 for working electrode can be first attached on the convex surface of the curved substrate 10 for working electrode before attaching the condenser lenses.

In further embodiments, the curved substrates are made of a general soda lime-based glass material or made by inserting a glass substrate between tempered glass plates for enhancing durability. In exemplary embodiments, the curved substrates are made of thin film glass or tempered glass according to the desired use.

In yet further embodiments, a translucent thin film formed of silver or gold nanoparticles whose diameter ranges from 1 nm to 10 nm by using an inkjet printing or pad printing method can be used as the metal electrodes to prevent the present invention from being limited to a specific design.

In exemplary embodiments, the conductive films 12 and 22 may be made of a conductive high molecular material, such as CNT(Carbon nanotube), graphene, PEDOT(Poly(3,4-ethylenedioxythiophene)poly(styrene sulfonate).

In further embodiments, an ionic liquid or polymer electrolyte may also be injected into the solar cell to enhance durability of the solar cell.

In yet further embodiments, the dye-sensitized solar cell module can be attached to the target structure by a sealant and then the sealant can be further applied along the outer periphery of the cell module, thus enhancing durability.

In yet further embodiments, a reflective film as is known to those skilled in the art and appropriate for the intended use is applied to the counter electrode to increase efficiency of the curved dye-sensitized solar cell.

In further embodiments, the reflective film can be attached on a concave surface of the curved substrate positioned inside of the vehicle, that is, the curved substrate 20 for counter electrode. The reflective film also can be selected so as to reflect light sequentially passing through the working electrode and the counter electrode toward the inside of the vehicle, thus increasing efficiency.

In further embodiments, functional glass, such as glass for blocking UV rays to prevent temperature in the vehicle from increasing, reflective glass, or glass for preventing noise can be applied to an electrode that is positioned inside of the vehicle or does not directly receive external light, for example, the counter electrode, within a range of not lowering efficiency of the solar cell.

In further embodiments, various function glass substrates (for example, a glass substrate having a water repellant function) can be additionally attached to an electrode that is positioned outside of the vehicle or directly receives external light, such as the working electrode, or the curved substrate can be configured of a functional glass substrate.

In yet further embodiments, a curved dye-sensitized solar cell is first manufactured and then sandwiched between tempered glass substrates, and can then be applied to, for example, a sunroof or panoramic roof of a vehicle.

The curved dye-sensitized solar cell according to the present invention can be applied to a sunroof or panoramic roof for a vehicle to produce electricity from sunlight or to provide ornamentality.

An illustrative process of manufacturing a curved dye-sensitized solar cell module according to examples of the present invention will now be described.

### EXAMPLES

To manufacture a curved substrate, a mold for injection molding was first prepared that has the same curvature as that of a sunroof of a selected vehicle. Two curved substrates, each having the same curvature as that of the sunroof and having a size of 300×300 mm², were manufactured using the mold. Then, unwanted material was removed by a washing process.

An FTO conductive film was coated on each of a concave surface of one of the curved substrates and a convex surface of the other curved substrate using SPD (Spray Prolysis Deposition) considering that a semiconductor oxide electrode film would be later joined with a catalytic electrode (see FIG. 2(a)).

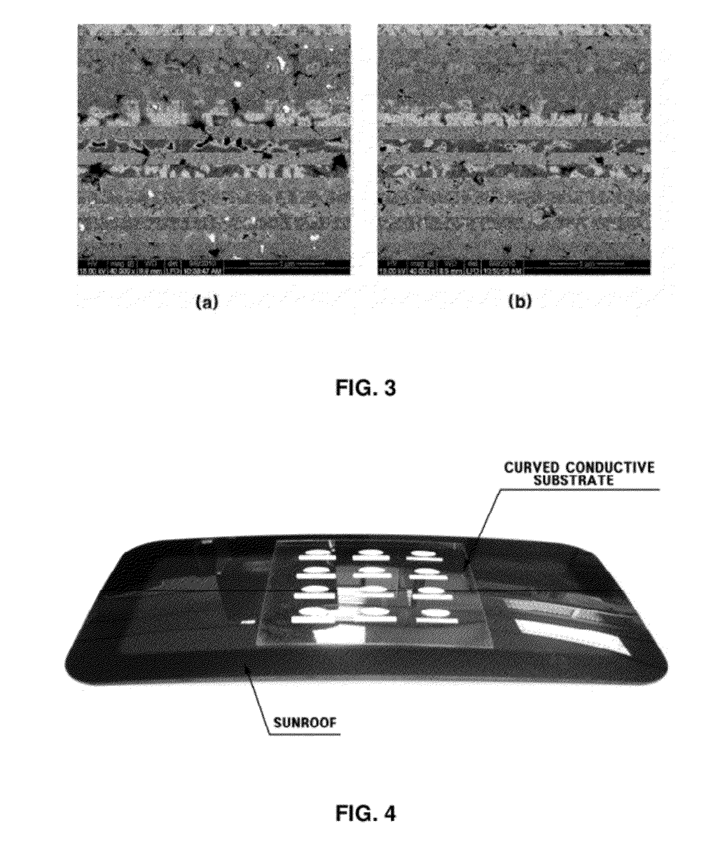

FIG. 3(b) shows an SEM image (particle size of 70 to 400 nm) of a curved conductive substrate obtained by coating an FTO film on the curved substrate and, as a sample for comparison, FIG. 3(a) shows a widely used flat conductive substrate (particle size of 70 to 500 nm, commercially available from Pilkington Corporation) formed with an FTO conductive film.

A dye-sensitized solar cell unit cell having a size of 25 mm² was manufactured using the curved conductive substrate thusly formed, and then, a performance test was carried out. The results showed that an optical voltage was 0.73V, an optical current was 14.3 mA/cm², FF(fill factor) was 59.5, and a photoelectric conversion efficiency was 6.2%.

These results are almost equal to those obtained by a dye-sensitized solar cell unit cell using a flat conductive substrate, for example, an optical voltage of 0.72V, an optical current of 13.8 mA/cm², FF of 62.8, and a photoelectric conversion efficiency of 6.3%. It has been also evaluated that the performance of the curved conductive substrate, such as transmittance, haze, or conductivity, is suitable for producing a dye-sensitized solar cell.

The curved conductive substrate having the concave surface coated with the conductive film was used for a working electrode. A pre-treatment was performed on the curved conductive substrate using TiCl₄, thus generating a thin TiO₂ film.

Next, a silver electrode was coated on each of the two curved conductive substrates (FIG. 2(b)), and then a silver electrode protection layer was coated on the silver electrode using glass frit (FIG. 2(c)).

Thereafter, TiO₂ was coated on the curved conductive substrate obtained by coating the conductive film on the concave film to thereby form a TiO₂ electrode film having a thickness of 15 um, and a platinum electrode was coated on the curved conductive substrate obtained by coating the conductive film on the convex surface (see FIG. 2(d)).

Before coating the platinum electrode, an injection hole was formed in the curved conductive substrate obtained by coating the conductive on the convex surface.

A curved surface screen printing method and a screen printer for curved substrates were used to form the silver electrode, the silver electrode protection film (glass frit), the TiO₂ electrode film, and the platinum electrode.

To evenly coat a film using the screen printing method, a jig having the same curvature as that of the curved substrates was prepared. While the tension of the plate for silver screen printing was adjusted, the electrode films including the silver electrode, the silver electrode protection film, the TiO₂ electrode film, and the platinum electrode, were coated on the curved substrate so as to have a uniform thickness by a screen printer for curved substrates having a squeezer with the same curvature as that of the curved substrate, with the curved substrate held by the jig.

TiO₂ paste was coated on a curved substrate having a size of 300×300 mm². A result showed that a TiO₂ pattern of a uniform thickness was printed. FIG. 4 illustrates that the curved substrate printed with the TiO₂ paste having the uniform thickness is arranged on a sunroof. It can be seen from that the curved substrate fits for the sunroof.

TABLE 1

| Thickness of | | | | |
|---|---|---|---|---|
| TiO₂ electrode film | (a) | (b) | (c) | Variation in thickness |
| Measured by | 12 um | 15 um | 12 um | Concave portion is |
| conventional | | | | thicker than side |
| screen printing | | | | portions by about |
| method | | | | 3 um with respect |
| | | | | to concave surface |
| Measured by | 10 um | 10 um | 10 um | Manufacture of |
| screen printing | | | | electrodes with |
| method for curved | | | | uniform thickness |
| coating(same spray | | | | |
| printing method) | | | | |

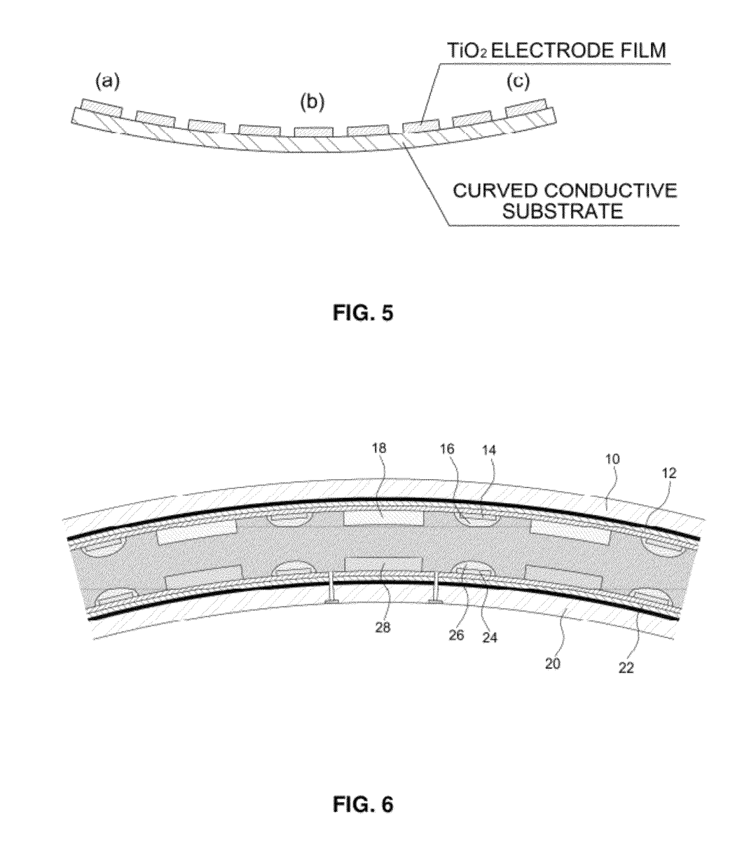

Table 1 shows thicknesses of the TiO₂ electrode film at various positions on a concave surface of the curved conductive substrate shown in FIG. 5.

In the case of using a conventional screen printer for flat substrate coating, a thickness difference of about 3 um or more occurred between a middle portion and a side portion due to the curvature of the curved substrate. However, in the case of using the screen printer for curved substrate coating according to the embodiments of the present invention, the TiO₂ electrode film could be coated to have a constant thickness.

A dye was adsorbed into the generated TiO₂ electrode film by an existing process (see FIG. 2(e)), and then the working electrode and the counter electrode were joined to each other by using SURLYN™ (see FIG. 2(f)).

An electrolyte was injected into the module through the injection hole formed in the curved substrate of the counter electrode (see FIG. 2(g)), and then the injection hole was sealed, thus completing a curved dye-sensitized solar cell module (FIG. 2(h)).

By the thusly manufactured curved dye-sensitized solar cell, in the case of aperture area, an open voltage (Voc) of 0.65V, a short voltage (Jsc) of 6.6 mA, FF of 53.5, and a photoelectric conversion efficiency of 2.30% were obtained in a module having a size of 100 cm². These results showed that the curved dye-sensitized solar cell is useful as a dye-sensitized solar cell.

The formation of a film having a uniform thickness on the curved substrate also can be achieved by changing the shape of the squeezer to have the same radius as the curvature of the curved substrate or by changing the tension of the plate for screen printing as well as by properly moving the jig mounted in the screen printer for curved substrate coating.

In joining the working electrode and counter electrode, the working electrode and the counter electrode can be joined to each other by a SURLYN tape while heating the working and counter electrodes, or by a UV curing machine, with the working and counter electrodes held by the jig that has the same curvature as that of the curved substrate and may be made of a material having excellent thermal transfer characteristics.

A curing agent can be uniformly applied on the curved electrode modules (working electrode and counter electrode) by the UV curing machine and uniformly exposed to light by moving the electrode modules using a jig having the same curvature as that of the curved substrate or by moving the jig along the curved surface of the electrode modules.

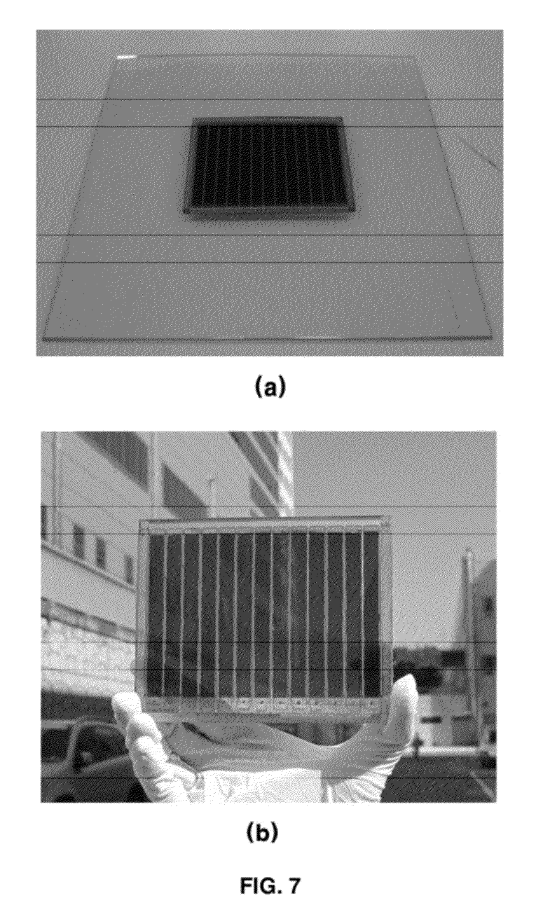

FIG. 7 shows views illustrating samples of a curved dye-sensitized solar cell manufactured using a curved substrate according to an embodiment of the present invention, wherein FIG. 7A illustrates that the curved dye-sensitized solar cell is placed on a curved glass plate (for example, the same curved glass plate as that shown in FIG. 4), and FIG. 7B is another illustration of the curved dye-sensitized solar cell.

As described above, in the present invention the non-planar and/or curved substrates are first manufactured and then a curved dye-sensitized solar cell is manufactured by using the non-planar/curved substrates. The non-planar/curved dye-sensitized solar cell thusly manufactured shows similar photoelectric conversion effects to those achieved by a flat dye-sensitized solar cell.

The non-planar/curved dye-sensitized solar cell of the present invention can be applied to a sunroof or panoramic roof for vehicles without deteriorating ornamentality. According to an embodiment, the non-planar/curved dye-sensitized solar cell also can be applied to curved glass for vehicles, such as door glass or wind shield.

The coating films, such as the conductive films 12 and 22, the metal electrodes 14 and 24, the metal electrode protection films 16 and 26, the semiconductor oxide electrode film 18, and the catalytic electrode 28, can be coated on the non-planar/curved substrates 10 and 20 using a screen printing method, an electro-spray method, a spray printing method, an inkjet printing method, MOCVD, or CVD.

To secure a uniform thickness for each of the films, a jig having the same curvature as that of the curved substrate can be mounted in each of the coating machines. As necessary, a motor may be mounted in the coating machine to slightly move the jig in X, Y, and Z directions to maintain a constant distance between the electrodes.

The invention has been described in detail with reference to the embodiments thereof. However, it will be appreciated by those skilled in the art that changes may be made in these embodiments without departing from the principles and spirit of the invention, the scope of which is defined in the appended claims and their equivalents.

1. A method of manufacturing a curved dye-sensitized solar cell comprising:
preparing two curved substrates, each having a curvature;
forming a first curved conductive substrate for a working electrode by coating a conductive film on a concave surface of one of the curved substrates and a second curved conductive substrate for a counter electrode by coating a conductive film on a convex surface of the other curved substrate;
coating a metal electrode and a protection film on each of the first and second curved conductive substrates;
forming the working electrode by coating a semiconductor oxide electrode film on a concave surface of the first curved conductive substrate and by adsorbing a dye in the semiconductor oxide electrode film;
forming the counter electrode by coating a catalytic electrode on a convex surface of the second curved conductive substrate; and
joining the working electrode with the counter electrode and injecting an electrolyte in between the working electrode and the counter electrode.

2. The method of claim 1, wherein each of the curved substrates is prepared by means of injection molding to have a predetermined rate of curvature.

3. The method of claim 1, wherein each of the curved substrates has a first curvature equal to a horizontal curvature of a portion of a vehicle to which the solar cell is applied and a second curvature equal to a vertical curvature of the portion of the vehicle.

4. The method of claim 1, wherein each of the curved substrates has the same curvature as a curvature of a sunroof or panoramic roof of a vehicle.

5. The method of claim 1, wherein a jig having the same curvature as a curvature of the curved substrates is mounted in a coating machine for a curved substrate, wherein the distance between a source for deposition of the coating machine and the curved substrates is constantly maintained at regular intervals to coat an electrode film having a uniform thickness with the curved substrates held by the jig.

6. The method of claim 1, wherein a squeezer having the same curvature as a curvature of the curved substrates is mounted in a screen printer for a curved substrate to coat an electrode film having a uniform thickness on the curved substrates, wherein the coating is performed while adjusting a tension of a plate for screen printing.

7. The method of claim 1, further comprising:
patterning the conductive films of the curved substrates, wherein a jig is mounted in a laser scriber for uniformly patterning the conductive films to maintain the distance between a laser part and the curved conductive substrates at regular intervals.

8. The method of claim 1, wherein a pre-treatment is performed on the semiconductor oxide electrode film of the first conductive substrate using a titanium tetrachloride-based compound or a titanium alkoxide-based compound.

9. The method of claim 1, wherein the conductive films, the metal electrodes, the protection films, the semiconductor oxide electrode film, and the catalytic film are coated to have a uniform thickness using a method selected from the group consisting of a screen printing method, an electrospray method, a spray printing method, an inkjet printing method, a MOCVD method, and a CVD method.

10. The method of claim 1, wherein one of color glass and a translucent color film is attached on a convex surface of the first curved conductive substrate and a concave surface of the second curved conductive substrate to enhance ornamentality.

11. The method of claim 1, wherein a reflection film is attached on a concave surface of the second curved conductive surface to increase efficiency.

12. The method of claim 1, wherein a condenser lens is mounted on a convex surface of the first curved substrate to increase efficiency.

13. A curved dye-sensitized solar cell manufactured by the method of claim 1.

14. A sunroof for a vehicle comprising the curved dye-sensitized solar cell of claim 13.

15. A panoramic roof for a vehicle comprising the curved dye-sensitized solar cell of claim 13.

16. Glass for a vehicle employing the curved dye-sensitized solar cell of claim 13.

17. A method of manufacturing a non-planar dye-sensitized solar cell comprising:
providing a first non-planar substrate and a second non-planar substrate, each of the first and second non-planar substrates being arranged so as to have a complementary opposing surface to each other;
forming a first non-planar conductive substrate as a working electrode and forming a second non-planar conductive substrate as a counter electrode, wherein said forming includes coating the opposing surface of the first non-planar substrate with a conductive film (first non-planar conductive substrate) and coating the opposing surface of the second non-planar conductive substrate with another conductive film (second non-planar conductive substrate);
wherein said forming further includes:
(a) coating each of the first and second non-planar conductive substrates with a metal electrode and a protection film,
(b) coating the first non-planar conductive substrate with a semiconductor oxide electrode film and adsorbing a dye in the semiconductor oxide electrode film, and
(c) coating the second non-planar conductive substrate with a catalytic electrode;
joining the working electrode with the counter electrode; and
injecting an electrolyte in between the working electrode and the counter electrode.

18. The method of claim 17, wherein each of the non-planar substrates is prepared using injection molding so that the opposing surfaces have a desired predetermined shape or configuration.

19. The method of claim 17, wherein each of the non-planar substrates has a first surface configuration corresponding to an opposing horizontal surface configuration of a portion of a vehicle to which the solar cell is to be applied, and a second surface configuration corresponding to an opposing vertical surface configuration of the portion of the vehicle.

20. A non-planar dye-sensitized solar cell manufactured by the method of claim 17.
